(19) United States
(12) Patent Application Publication
(10) Pub. No.: US 2026/0282368 A1
(43) Pub. Date: Sep. 17, 2026

(54) SEMICONDUCTOR MEMORY DEVICE AND MANUFACTURING METHOD THEREOF

(71) Applicant: Kioxia Corporation, Minato-ku, Tokyo (JP)

(72) Inventor: Ken HIGUCHI, Nagoya, Aichi (JP)

(73) Assignee: Kioxia Corporation, Minato-ku, Tokyo (JP)

(21) Appl. No.: 19/314,151

(22) Filed: Aug. 29, 2025

(30) Foreign Application Priority Data
Mar. 17, 2025 (JP) 2025-042840

(51) Int. Cl. H10B 43/35; H10B 41/10; H10B 41/27; H10B 41/35; H10B 41/41; H10B 43/10; H10B 43/27; H10B 43/40

(52) U.S. Cl. CPC H10B 43/35; H10B 41/10; H10B 41/27; H10B 41/35; H10B 41/41; H10B 43/10; H10B 43/27; H10B 43/40

(57) ABSTRACT

A semiconductor memory device includes a first one of a plurality of word lines. The first word line, in a cross-section, includes an end surface with a center portion and an end portion. A first insulating layer, a second insulating layer, a third insulating layer, and a semiconductor layer are provided in such an order from the end surface of the first word line in a lateral direction. A first thickness of the first insulating layer corresponding to the end portion of the first word line and a second thickness of the first insulating layer corresponding to the center portion of the first word line are different, while the second insulating layer, the third insulating layer, and the semiconductor layer each have a sidewall linearly extending in a vertical direction.

### CROSS-REFERENCE TO RELATED APPLICATION

This application is based upon and claims the benefit of priority from Japanese Patent Application No. 2025-042840, filed Mar. 17, 2025, the entire contents of which are incorporated herein by reference.

### FIELD

Embodiments described herein relate generally to a semiconductor memory device and a manufacturing method thereof.

### BACKGROUND

NAND flash memories capable of storing data in a nonvolatile manner are known.

### DESCRIPTION OF THE DRAWINGS

FIG. 1 is a block diagram illustrating a circuit configuration of a semiconductor memory device according to a first embodiment;

FIG. 2 is a circuit diagram illustrating a block in a memory cell array according to the first embodiment;

FIG. 3 is a schematic view illustrating an example of a planar layout of the semiconductor memory device according to the first embodiment;

FIG. 4 is a diagram illustrating an example of a planar layout of the memory cell array according to the first embodiment;

FIG. 5 is a diagram illustrating another example of the planar layout of the memory cell array according to the first embodiment;

FIG. 6 is a cross-sectional view illustrating a memory region in the memory cell array according to the first embodiment;

FIG. 7 is a cross-sectional view of a memory pillar in the memory cell array according to the first embodiment;

FIG. 8 is a cross-sectional view illustrating a lead region in the memory cell array according to the first embodiment;

FIG. 9 is a cross-sectional view illustrating a word line and the memory pillar in the memory cell array according to the first embodiment;

FIG. 10 is a flowchart illustrating a method of manufacturing the semiconductor memory device according to the first embodiment;

FIG. 11 is a cross-sectional view illustrating the method manufacturing the semiconductor memory device according to the first embodiment;

FIG. 12 is a cross-sectional view illustrating the method of manufacturing the semiconductor memory device according to the first embodiment;

FIG. 13 is a cross-sectional view illustrating the method of manufacturing the semiconductor memory device according to the first embodiment;

FIG. 14 is a cross-sectional view illustrating the method of manufacturing the semiconductor memory device according to the first embodiment;

FIG. 15 is a cross-sectional view illustrating the method of manufacturing the semiconductor memory device according to the first embodiment;

FIG. 16 is a cross-sectional view illustrating the method of manufacturing the semiconductor memory device according to the first embodiment;

FIG. 17 is a cross-sectional view illustrating the method of manufacturing the semiconductor memory device according to the first embodiment;

FIG. 18 is a cross-sectional view illustrating the method of manufacturing the semiconductor memory device according to the first embodiment;

FIG. 19 is a cross-sectional view illustrating the method of manufacturing the semiconductor memory device according to the first embodiment;

FIGS. 20A-20C are each a cross-sectional view illustrating a stacked structure of a memory hole opening region and a non-opening region in the semiconductor memory device according to the first embodiment;

FIG. 21 is a cross-sectional view illustrating a word line and a memory pillar in a memory cell array according to a second embodiment;

FIGS. 22A-22C are each a cross-sectional view illustrating a stacked structure of a memory hole opening region and a non-opening region in a semiconductor memory device according to the second embodiment;

FIG. 23 is a cross-sectional view illustrating a word line and a memory pillar in a memory cell array according to a third embodiment; and

FIGS. 24A-24C are each a cross-sectional view illustrating a stacked structure of a memory hole opening region and a non-opening region in a semiconductor memory device according to the third embodiment.

### DETAILED DESCRIPTION

Embodiments provide a semiconductor memory device capable of improving characteristics of a memory cell and a manufacturing method thereof.

In general, according to one embodiment, a semiconductor memory device includes: a plurality of word lines extending in a first direction and stacked in a second direction intersecting the first direction; and a pillar penetrating the plurality of word lines in the second direction and including g a first insulating layer, a second insulating layer, a third insulating layer, and a semiconductor layer extending in the second direction. A first one of the plurality of word lines, in a cross-section extended along the first and second directions, includes an end surface with a center portion and an end portion. The first insulating layer, the second insulating layer, the third insulating layer, and the semiconductor layer are provided in such an order from the end surface of the first word line in the first direction. A first thickness of the first insulating layer corresponding to the end portion of the first word line and a second thickness of the first insulating layer corresponding to the center portion of the first word line are different, while the second insulating layer, the third insulating layer, and the semiconductor layer each have a sidewall linearly extending in the second direction.

According to an embodiment, a method of manufacturing a semiconductor memory device includes: forming a stacked structure by alternately stacking a first insulating layer and a sacrifice layer on a substrate; forming a hole in the stacked structure in the first direction; oxidizing the sacrifice layer exposed in the hole; forming a second insulating layer in the hole after oxidizing the sacrifice layer; forming a nitride layer on the second insulating layer in the hole; forming a third insulating layer on the nitride layer in the hole; and forming a semiconductor layer on the third insulating layer in the hole.

In the following description, common reference numerals are given to elements that have the same functions and configurations. The following embodiments are merely examples of devices and methods embodying the technical concepts of the embodiments and do not limit materials, shapes, structures, and arrangements of the elements to those described below.

The drawings to be referenced to below are schematic or conceptual in nature. Dimensions and ratios of the drawings do not necessarily correspond to actual dimensions and ratios. In some drawings that illustrate structures, an XYZ orthogonal coordinate system is used. An X direction extends along an X-axis. A Y direction extends along a Y-axis. A Z direction extends along a Z-axis. The X direction and the Y direction are orthogonal to each other. The Z direction is orthogonal to each of the X direction and the Y direction and corresponds to a vertical direction relative to a surface of a semiconductor substrate. A side with a larger coordinate on the X-axis (X direction), the Y-axis (Y direction), or the Z-axis (Z direction) may be referred to as a positive direction, while a side with a smaller coordinate may be referred to as a negative direction. The positive direction of the Z-axis may be referred to as an upper side, and the negative direction may be referred to as a lower side. The positive direction of the X-axis or the Y-axis may be referred to as a right side, while the negative direction may be referred to as a left side. In a plan view, hatching is added as appropriate to improve visibility of the drawings. The hatching added to the plan view is not necessarily related to materials or characteristics of elements to which the hatching is added. In both a plan view and a cross-sectional view, wirings, contact plugs, and interlayer insulating films are appropriately omitted to improve visibility of the drawings.

Hereinafter, a semiconductor memory device according to an embodiment will be described. A three-dimensionally stacked NAND flash memory in which memory cell transistors are stacked three-dimensionally above a semiconductor substrate will be described as an example of the semiconductor memory device. The NAND flash memory is a semiconductor memory capable of storing data in a nonvolatile manner.

For example, in the semiconductor memory device, a plurality of stacked word lines may be formed by forming a stacked structure of an oxide layer and a nitride layer on a substrate, and then replacing the nitride layer with a conductive layer. In recent years, word lines are stacked highly, and thus it is necessary to reduce a stacking interval between the stacked word lines (or a stacking interval of the oxide layer and the nitride layer) (hereinafter referred to as a stacking pitch). However, reduction in the stacking pitch between the word lines may deteriorate characteristics of a memory cell.

An embodiment proposes a structure capable of reducing deterioration generated in characteristics of a memory cell due to reduction in a stacking pitch between word lines and a manufacturing method thereof.

### 1. First Embodiment

A semiconductor memory device according to a first embodiment will be described.

### 1.1. Circuit Configuration of Semiconductor Memory Device

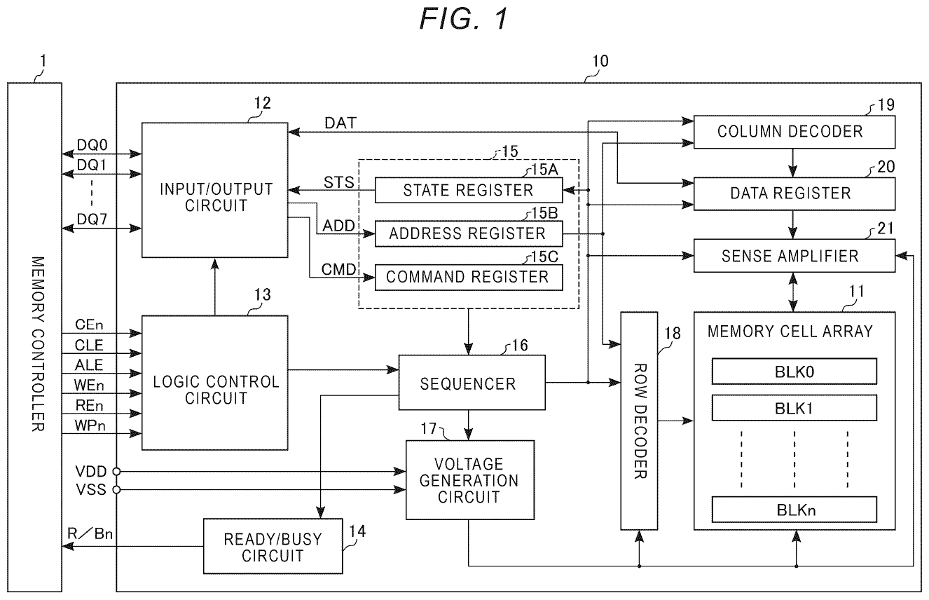

First, a circuit configuration of the semiconductor memory device according to the first embodiment will be described. FIG. 1 is a block diagram illustrating the circuit configuration of the semiconductor memory device according to the first embodiment.

A semiconductor memory device 10 according to the first embodiment includes, for example, a NAND flash memory and stores data in a nonvolatile manner. A memory controller 1 is connected to the semiconductor memory device 10 via a NAND bus. The semiconductor memory device 10 is controlled by the memory controller 1.

The semiconductor memory device 10 includes a memory cell array 11, an input/output circuit 12, a logic control circuit 13, a ready/busy circuit 14, a register group 15, a sequencer (or a control circuit) 16, a voltage generation circuit 17, a row decoder 18, a column decoder 19, a data register 20, and a sense amplifier 21. The register group 15 includes a status register 15A, an address register 15B, and a command register 15C.

The memory cell array 11 includes one or a plurality of blocks BLK0, BLK1, BLK2, . . . , and BLKn (where n is an integer of 0 or more). Each of the plurality of blocks BLK0 to BLKn includes a plurality of memory cell transistors (hereafter also referred to as memory cells) associated with rows and columns. The memory cell transistor is a nonvolatile memory cell capable of electrically executing erasing and programming. The memory cell array 11 includes a plurality of word lines, a plurality of bit lines, and a source line for applying voltages to the memory cell transistors. A specific configuration of the block BLKn will be described below.

The input/output circuit 12 and the logic control circuit 13 are connected to the memory controller 1 via input/output terminals (or NAND buses). The input/output circuit 12 transmits and receives an I/O signal DQ (for example, DQ0, DQ1, DQ2, . . . , and DQ7) via an input/output terminal to and from the memory controller 1. The I/O signal DQ is used for communication of a command, an address, and data.

The logic control circuit 13 receives an external control signal from the memory controller 1 via an input/output terminal (or a NAND bus). The external control signal includes, for example, a chip enable signal CEn, a command latch enable signal CLE, an address latch enable signal ALE, a write enable signal WEn, a read enable signal REn, and a write protection signal WPn. “n” suffixed to a signal name indicates that the signal is active low.

The chip enables signal CEn enables selection of a semiconductor memory device 10 when a plurality of semiconductor memory devices 10 are mounted, and is asserted when the semiconductor memory device 10 is selected. The command latch enable signal CLE enables a command transmitted as the signal DQ to be latched in the command register 15C. The address latch enable signal ALE enables an address transmitted as the signal DQ to be latched in the address register 15B. The write enable signal WEn enables data transmitted as the signal DQ to be stored in the input/output circuit 12. The read enable signal REn enables data read from the memory cell array 11 to be output as the signal DQ. The write protection signal WPn is asserted when a write operation and an erase operation on the semiconductor memory device 10 is prohibited.

The ready/busy circuit 14 generates a ready/busy signal R/Bn under control of the sequencer 16. The ready/busy signal R/Bn indicates whether the semiconductor memory device 10 is in a ready state or a busy state. The ready state indicates that the semiconductor memory device 10 is able to receive a command from the memory controller 1. The busy state indicates that the semiconductor memory device 10 is not able to receive a command from the memory controller 1. The memory controller 1 can know whether the semiconductor memory device 10 is in the ready state or the busy state by receiving the ready/busy signal R/Bn from the semiconductor memory device 10.

The status register 15A stores status information STS necessary for an operation of the semiconductor memory device 10. The status register 15A transmits the status information STS to the input/output circuit 12 according to an instruction of the sequencer 16.

The address register 15B stores the address ADD transmitted from the input/output circuit 12. The address ADD includes a row address and a column address. The row address includes, for example, a block address for designating the operation target block BLKn and a page address for designating the operation target word line WL in the designated block.

The command register 15C stores the command CMD transmitted from the input/output circuit 12. The command CMD includes, for example, a write command that instructs the sequencer 16 to execute a write operation, a read command that instructs the sequencer 16 to execute a read operation, and an erase command that instructs the sequencer 16 to execute an erase operation.

In the status register 15A, the address register 15B, and the command register 15C, for example, a static random access memory (SRAM) is used.

The sequencer 16 receives a command from the command register 15C and controls the overall semiconductor memory device 10 according to a sequence based on the command.

The sequencer 16 controls the voltage generation circuit 17, the row decoder 18, the column decoder 19, the data register 20, the sense amplifier 21, and the like to execute the write operation, the read operation, and the erase operation. Specifically, the sequencer 16 controls the voltage generation circuit 17, the row decoder 18, the column decoder 19, the data register 20, and the sense amplifier 21 based on a write command received from the command register 15C to write data in a plurality of memory cell transistors designated by the address ADD. The sequencer 16 controls the voltage generation circuit 17, the row decoder 18, the column decoder 19, the data register 20, and the sense amplifier 21 based on a read command received from the command register 15C to read data from a plurality of memory cell transistors designated by the address ADD. The sequencer 16 controls the voltage generation circuit 17, the row decoder 18, the column decoder 19, the data register 20, and the sense amplifier 21 based on an erase command received from the command register 15C to erase data stored in a block designated by the address ADD. A circuit including the column decoder 19, the data register 20, and the like is referred to as a column-based control circuit.

The voltage generation circuit 17 receives a power voltage VDD and a ground voltage VSS via a supply terminal from outside of the semiconductor memory device 10. The supply voltage VDD is an external voltage supplied from outside of the semiconductor memory device 10. The ground voltage VSS is an external voltage supplied from outside of the semiconductor memory device 10 and is, for example, 0 V.

The voltage generation circuit 17 generates a plurality of voltages necessary for the write operation, the read operation, and the erase operation using the supply voltage VDD. The voltage generation circuit 17 supplies the generated voltages to the memory cell array 11, the row decoder 18, the sense amplifier 21, and the like.

The row decoder 18 receives a row address from the address register 15B and decodes the row address. The row decoder 18 selects a block from a plurality of blocks based on a decoding result of the row address and further selects the word line WL in the selected block BLKn. The row decoder 18 transmits the plurality of voltages supplied from the voltage generation circuit 17 to the selected block BLKn.

The column decoder 19 receives a column address from the address register 15B and decodes the column address. The column decoder 19 selects a latch circuit in the data register 20 based on a decoding result of the column address.

The data register 20 includes a plurality of latch circuits. The latch circuit temporarily stores write data or read data.

During the read operation of data, the sense amplifier 21 senses and amplifies data read from the memory cell transistor to the bit line. The sense amplifier 21 temporarily stores read data DAT read from the memory cell transistor and transmits the stored read data DAT to the data register 20. During the write operation of data, the sense amplifier 21 temporarily stores write data DAT transmitted from the input/output circuit 12 via the data register 20. The sense amplifier 21 transmits the write data DAT to the bit line.

Next, a circuit configuration of the memory cell array 11 in the semiconductor memory device 10 according to the first embodiment will be described. As described above, the memory cell array 11 includes the plurality of BLK0 to BLKn. Hereinafter, a circuit configuration of the block BLKn will be described.

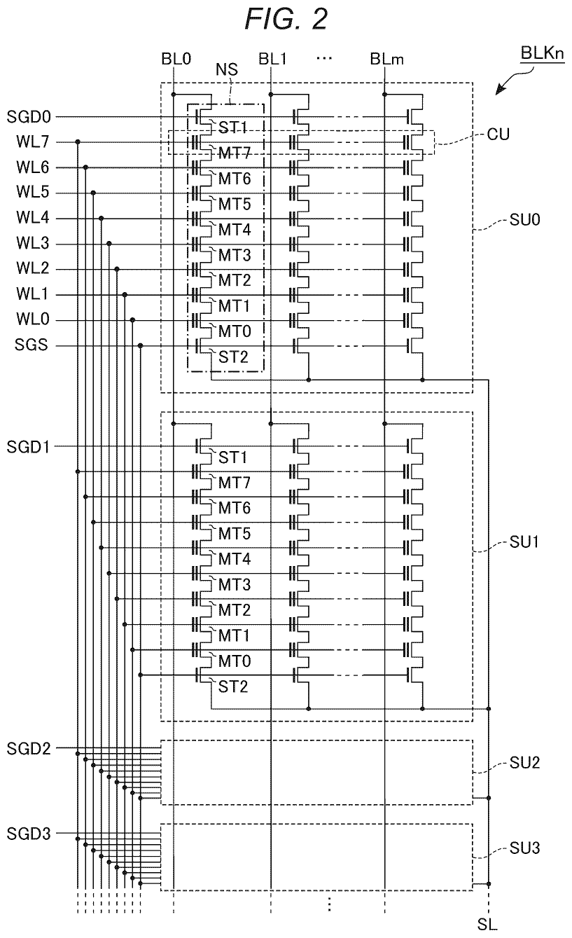

FIG. 2 is a circuit diagram illustrating the block BLKn in the memory cell array 11. The block BLKn includes, for example, a plurality of string units SU0, SU1, SU2, and SU3. Hereinafter, when described as a string unit SU, it is assumed that the string unit SU indicates each of the string units SU0 to SU3. The string unit SU includes a plurality of NAND strings (or memory strings) NS.

Here, to facilitate description, in the illustrated example, the NAND string NS includes, for example, eight memory cell transistors MT0, MT1, MT2, . . . , and MT7 and two select transistors ST1 and ST2. Hereinafter, when described as a memory cell transistor MT, it is assumed that the memory cell transistor MT indicates each of the memory cell transistors MT0 to MT7.

The memory cell transistor MT includes a control gate and a charge storage layer, and stores data in a nonvolatile manner. The memory cell transistors MT0 to MT7 are connected in series between a source of the select transistor ST1 and a drain of the select transistor ST2. The memory cell transistor MT is able to store data of 1-bit data or data of 2-bit or more.

Gates of the plurality of select transistors ST1 in the string unit SU0 are connected to a select gate line SGD0. Similarly, gates of the select transistors ST1 of each of the string units SU1 to SU3 are connected to the gate lines SGD1 to SGD3, respectively. The select gate lines SGD0 to SGD3 are each controlled independently by the row decoder 18.

Gates of the plurality of select transistors ST2 in the string unit SU0 are connected to the select gate line SGS. Similarly, gates of the select transistors ST2 of each of the string units SU1 to SU3 are connected to the select gate line SGS. Different select gate lines SGS may be connected to the gates of the select transistors ST2 of each of the string units SU0 to SU3. The select transistors ST1 and ST2 are used to select the string unit SU in various operations.

Control gates of the memory cell transistors MT0 to MT7 in the block BLKn are connected to word lines WL0 to WL7, respectively. Each of the word lines WL0 to WL7 is controlled independently by the row decoder 18.

Each of bit lines BL0, BL1, BL2, . . . , and BLm (where m is a natural number of 0 or more) is connected to the plurality of blocks BLK0 to BLKn and is connected to one NAND string NS in the string unit SU in the block BLKn. That is, each of the bit lines BL0 to BLm is connected to drains of the select transistors ST1 of the plurality of NAND strings NS in the same column among the NAND strings NS arranged in a matrix configuration in the block BLKn. The source line SL is connected to the plurality of blocks BLK0 to BLKn. That is, the source line SL is connected to sources of the plurality of select transistors ST2 in the block BLKn.

In short, the string unit SU includes a plurality of NAND strings NS connected to different bit lines BL and connected to the same select gate line SGD. The block BLKn includes a plurality of string units SU using a common word line WL. The memory cell array 11 includes the plurality of blocks BLK0 to BLKn using a common bit line BL.

The block BLKn is, for example, erasing units of data. That is, data stored in the memory cell transistors MT in the block BLKn is collectively erased. Data in a plurality of blocks is erased sequentially for each block. Data in a plurality of blocks are erased simultaneously in parallel. Data may be erased in units of string units SU or may be erased in units smaller than string units SU.

A plurality of memory cell transistors sharing a word line in one string unit SU are referred to as a cell unit CU. A collection of 1-bit data stored by the plurality of memory cell transistors MT in the cell unit CU is referred to as a page. Storage capacity of the cell unit CU varies depending on the number of bits of data stored by the memory cell transistor MT. For example, the cell unit CU stores 1-page data when each memory cell transistor MT stores 1-bit data, stores 2-page data when each memory cell transistor MT stores 2-bit data, and stores 3-page data when each memory cell transistor MT stores 3-bit data.

The write operation and the read operation on the cell unit CU is executed in units of pages. In other words, the read operation and the write operation are collectively executed on the plurality of memory cell transistors MT connected to one word line WL provided in one string unit SU.

The number of string units in the block BLKn is not limited to SU0 to SU3, and any number of string units can be set. The number of NAND strings NS in the string unit SU, and the number of memory cell transistors and select transistors in the NAND string NS can be set to any number. The memory cell transistor MT may be a metal-oxide-nitride-oxide-silicon (MONOS) type transistor using an insulating film as a charge storage layer or may be a floating gate (FG) type transistor using a conductive layer as a charge storage layer.

### 1.2. Configuration of Semiconductor Memory Device

An example of a configuration of the semiconductor memory device 10 according to the first embodiment will be described.

### 1.2.1. Planar Layout of Semiconductor Memory Device

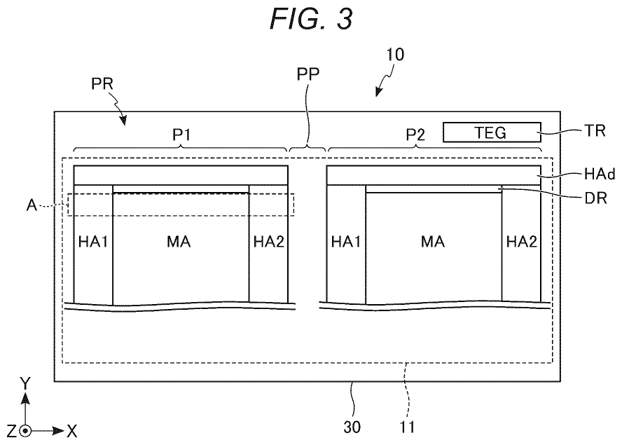

An example of a planar layout of the semiconductor memory device 10 according to the first embodiment will be described with reference to FIG. 3. FIG. 3 is a schematic view illustrating an example of the planar layout of the semiconductor memory device 10. In FIG. 3, two planes P1 and P2 corresponding to the memory cell array 11 are illustrated and peripheral circuits such as the row decoder 18, the sense amplifier 21, and the sequencer 16 are not illustrated. Here, for example, the peripheral circuits are provided below the planes P1 and P2, that is, in a negative direction of the Z direction.

As illustrated in FIG. 3, the semiconductor memory device 10 includes the memory cell array 11 including the planes P1 and P2, and a test element group (TEG) on a substrate (for example, a semiconductor substrate) 30. Each of the planes P1 and P2 is a memory cell group configured to be able to execute the write operation, the read operation, and the erase operation independently. The TEG includes, for example, an element such as a transistor for characteristic evaluation or a pattern for process evaluation.

Each of the planes P1 and P2 includes a memory region MA, lead regions (or step regions) HA1 and HA2, and a dummy lead region HAd. The memory region MA is a region where the plurality of memory cells MT and a plurality of word lines WL and bit lines BL connected to the memory cell transistors MT are disposed. The lead regions HA1 and HA2 are regions having a step structure in which the plurality of word lines WL are led out in a step shape and contact plugs connected to the word lines WL are disposed. The dummy lead region HAd is a pseudo-lead region having a step structure in which the contact plugs are not disposed.

In each of the planes P1 and P2, the lead regions HA1 and HA2 are disposed on both sides of the memory region MA in the X direction. That is, the memory region MA is disposed between the lead regions HA1 and HA2. The dummy lead region HAd is disposed at one end of the memory region MA in the Y direction.

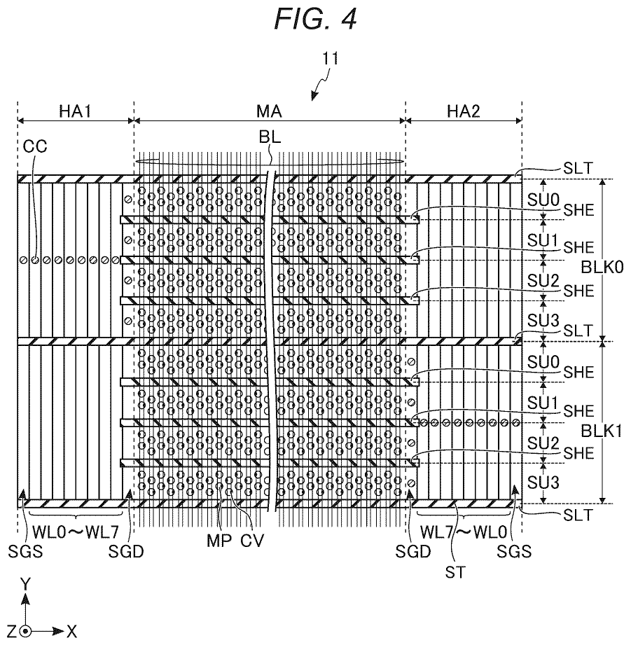

Next, layouts of lead regions HA1 and HA2 and the memory region MA will be described with reference to FIG. 4. FIG. 4 is a diagram illustrating an enlarged region indicated by A in FIG. 3 and a layout in which the memory region MA is disposed between the lead regions HA1 and HA2. FIG. 4 illustrates a region corresponding to the blocks BLK0 and BLK1.

As illustrated in FIG. 4, the memory cell array 11 includes a plurality of slits SLT and SHE, a plurality of memory pillars MP, a plurality of bit lines BL, and a plurality of contact plugs CC and CV.

The plurality of slits SLT and SHE are arranged in the Y direction. For example, three slits SHE are arranged between one slit SLT and another slit SLT. Each of the slits SLT and SHE extends in the X direction. Each slit SLT crosses the memory region MA and the lead regions (or step regions) HA1 and HA2. Each slit SHE crosses the memory region MA and the select gate lines SGD in the lead regions HA1 and HA2. That is, each slit SLT or SHE divides and insulates wiring layers (or conductive layers) adjacent to each other via the slit SLT or SHE. Specifically, each slit SLT divides and insulates a plurality of wiring layers corresponding to the word lines WL0 to WL7 and the select gate lines SGD and SGS. Each slit SHE divides and insulates a plurality of wiring layers corresponding to the word lines WL0 to WL7 and the select gate lines SGD.

Each memory pillar MP functions as, for example, one NAND string NS. For example, a plurality of memory pillars MP are disposed in a staggered arrangement of four columns in the memory region MA and a region between the slits SLT or SHE adjacent to each other. In the example, each region divided by the slits SLT or SHE corresponds to one string unit SU. The number and arrangement of memory pillars MP between the slits SLT or SHE adjacent to each other can be changed as appropriate.

The plurality of bit lines BL are arranged in the X direction. Each bit line BL extends in the Y direction. Each bit line BL overlaps with at least one memory pillar MP for each string unit SU. In the example, two bit lines BL overlap with one memory pillar MP. The contact plug CV is provided between the memory pillar MP and one bit line BL among the plurality of bit lines BL overlapping the memory pillar MP. Each memory pilar MP is connected to the associated bit line BL via the contact plug CV.

In each of the lead regions HA1 and HA2, each of the select gate line SGS, the word lines WL0 to WL7, and the select gate line SGD includes a portion that does not overlap with a wiring layer (or a conductive layer) of an upper layer. The shape of the portion that does not overlap with the wiring layer of the upper layer is referred to as a terrace, a step, a rimstone, or the like. Hereinafter, in the present specification, the portion that does not overlap with the wiring layer of the upper layer is referred to as a terrace portion. Specifically, the terrace portion is provided between the select gate line SGS and the word line WL0, between the word lines WL0 and WL1, between the word lines WL1 and WL2, between the word lines WL2 and WL3, between the word lines WL3 and WL4, between the word lines WL4 and WL5, between the word lines WL5 and WL6, between the word lines WL6 and WL7, and between the word line WL7 and the select gate line SGD, respectively.

Each of the plurality of contact plugs CC is used between the row decoder 18 and each of the word lines WL0 to WL7 and the select gate lines SGS and SGD. Each contact plug CC is disposed on the terrace portion of each of the word lines WL0 to WL7 and the select gate lines SGS and SGD. Here, an example is described in which the contact plugs CC on the terrace portions of the word lines WL0 to WL7 and the select gate lines SGS and SGD are disposed in one line in the X direction, but the contact plugs CC may be disposed to be each shifted in the Y direction.

For example, the contact plugs CC associated with the block BLK0 are disposed in the lead region HA1, and the contact plugs CC associated with the block BLK1 are disposed in the lead region HA2. In other words, for example, the blocks BLK of even numbers are connected to the row decoder 18 via the contact plug CC in the lead region HA1. The blocks BLK of odd numbers are connected to the row decoder 18 via the contact plug CC in the lead region HA2.

In the planar layout of the memory cell array 11, the memory region MA and the lead regions HA1 and HA2 described above are disposed repeatedly in the Y direction.

In FIGS. 3 and 4, a layout where the memory region MA is disposed between the lead regions HA1 and HA2 is illustrated. A lead region HA may be disposed to be interposed between a memory region MA1 and a memory region MA2.

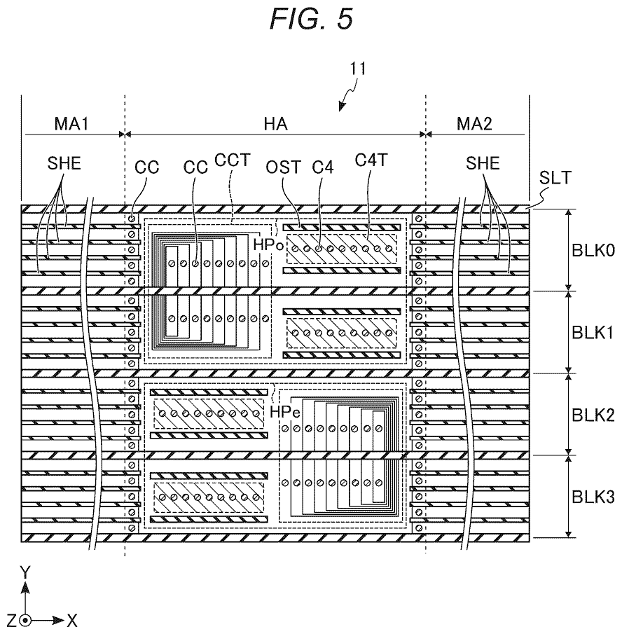

FIG. 5 is a diagram illustrating a layout in which the lead region HA is interposed between the memory regions MA1 and MA2. FIG. 5 illustrates regions corresponding to the blocks BLK0 to BLK3.

As illustrated in FIG. 5, the memory cell array 11 includes the plurality of slits SLT and SHE. The memory cell array 11, for example, divides the memory regions MA1 and MA2 and the lead regions HA in the X direction. The lead region HA is disposed between the memory regions MA1 and MA2.

The plurality of slits SLT each extend in the X direction and are arranged in the Y direction. Each slit SLT crosses the memory regions MA1 and MA2 and the lead regions HA in the X direction in a boundary region between the blocks BLK adjacent to each other.

The plurality of slits SHE are disposed in each of the memory regions MA1 and MA2. The plurality of slits SHE corresponding to the memory region MAL each cross the memory region MA1 and are arranged in the Y direction. The plurality of slits SHE corresponding to the memory region MA2 each cross the memory region MA2 and are arranged in the Y direction.

The lead region HA includes a plurality of lead portions HP (HPo and HPe) arranged in the Y direction. The lead portions HP are disposed at intervals of two blocks BLK. In other words, the lead portions HP are each disposed in a region interposed between two slits SLT sandwiching two blocks BLK adjacent to each other in the lead region HA.

Hereinafter, an odd lead portion HP is also referred to as HPo, and an even lead portion HP is also referred to as HPe. For example, the lead portions HPo are disposed in each of a pair including blocks BLK0 and BLK1 and a pair including blocks BLK4 and BLK5 (not illustrated) in the lead region HA. The lead portions HPe are disposed in each of a pair including blocks BLK2 and BLK3 and a pair including blocks BLK6 and BLK7 (not illustrated) in the lead region HA.

Each lead portion HP includes a contact region CCT and two contact regions C4T. The contact region CCT is a region having a step structure of stacked wiring layers. In the contact region CCT, a plurality of contact plugs CC are disposed. The contact region C4T is an insulating region that penetrates the stacked wiring layers. In the insulating region of the contact region C4T, a plurality of contact plugs C4 are disposed. The contact region CCT and two contact regions C4T are arranged in the X direction.

In each lead portion HP, each of two contact regions C4T are provided for two blocks BLK adjacent to each other. Each contact region C4T is interposed between two insulating layers OST arranged apart from each other in the Y direction. Each insulating layer OST extends in the X and Z directions. The stacked wiring layers in each block BLK are electrically connected between the memory areas MA1 and MA2 while bypassing the contact regions C4T.

In the lead region HA, the contact regions CCT and CAT of each lead portion HP are disposed in a staggered arrangement. Specifically, arrangement of the contact regions CCT and C4T in the lead portion HPe is similar to arrangement of the contact regions CCT and CAT in the lead portion HPo reversed in the X direction. That is, in the lead portion HPo, the contact region CCT is disposed on the memory region MA1 side and the contact region C4T is disposed on the memory region MA2 side. In the lead portion HPe, the contact region C4T is disposed on the memory region MA1 side and the contact region CCT is disposed on the memory region MA2 side.

In the lead portion HA, a wiring layer corresponding to the select gate line SGD includes a terrace portion that does not overlap with the wiring layer of the upper layer. In the contact region CCT, each of the wiring layers corresponding to the select gate line SGS and the word lines WL0 to WL7 includes a terrace portion that does not overlap with the wiring layer of the upper layer. The contact region CAT is a region that does not include the wiring layers corresponding to the select gate line SGS and the word lines WL0 to WL7.

A shape of the terrace portion in the lead region HA is similar to a step, a terrace, a rimstone, or the like. Specifically, a stepped difference is formed between the select gate line SGS and the word line WL0, between the word lines WL0 and WL1, . . . , between the word lines WL6 and WL7, and between the word line WL7 and the select gate line SGD, respectively. In the example of FIG. 5, a part of each of the word lines WL0 to WL7 is provided in a step shape that has a stepped difference in the X direction.

The plurality of contact plugs CC are each provided on the terrace portion of each of the wiring layers corresponding to the select gate line SGS, the word lines WL0 to WL7, and the select gate line SGD in each block BLK. The plurality of contact plugs C4 are provided in the contact region CAT to correspond to the select gate line SGS and the word lines WL0 to WL7.

The wiring layers corresponding to the select gate line SGS, the word lines WL0 to WL7, and the select gate line SGD are electrically connected to the row decoder 18 via, for example, a pair including contact plugs CC and C4. In the example, the select gate line SGS and the word lines WL0 to WL7 are each connected to the row decoder 18 via the pair including contact plugs CC and C4 disposed in the lead region HA. The select gate line SGD may be connected to the row decoder 18 via a similar path to the word lines WL or may be connected to the row decoder 18 via a region outside of the lead region HA.

In the layout illustrated in FIG. 3, a region DR where a dummy block may be provided (hereinafter referred to as a dummy region) is disposed between one end of the memory region MA and the dummy lead region HAD. A region TR where the TEG is provided (hereinafter referred to as a TEG region) is disposed between an edge of the substrate 30 and the plane P2. The semiconductor memory device 10 includes a region PP between the planes P1 and P2 (hereinafter referred to as an inter-plane region) and a region PR between the edge and the plane of the substrate 30 (hereinafter referred to as an edge region).

In the layout illustrated in FIG. 5, the contact region C4T where the contact plug C4 is provided is disposed in the lead region HA between the memory regions MA1 and MA2. The contact plug C4 is, for example, a contact plug for electrically connecting the word line WL to the row decoder 18. The contact plug C4 is provided from a pad above the memory cell array 11 to a pad connected to the row decoder 18 below the memory cell array 11 to penetrate an insulating layer 32 (for example, a silicon oxide layer) and a sacrifice layer 60 (for example, a nitride layer) described below. In a region where the word lines WL and the select gate lines SGS and SGD are disposed, the sacrifice layer 60 is replaced with a conductive layer 42. In the contact region C4T, the sacrifice layer 60 is not replaced with the conductive layer 42.

In the dummy region DR, the TEG region TR, the inter-plane region PP, the edge region PR, and the contact region C4T described above, the sacrifice layer not replaced with the word lines WL and the select gate lines SGS and SGD remains after manufacturing of the semiconductor memory device 10 ends. In the example, the sacrifice layer is, for example, a silicon nitride layer and a silicon oxynitride layer.

### 1.2.2. Cross-Sectional Structure of Semiconductor Memory Device

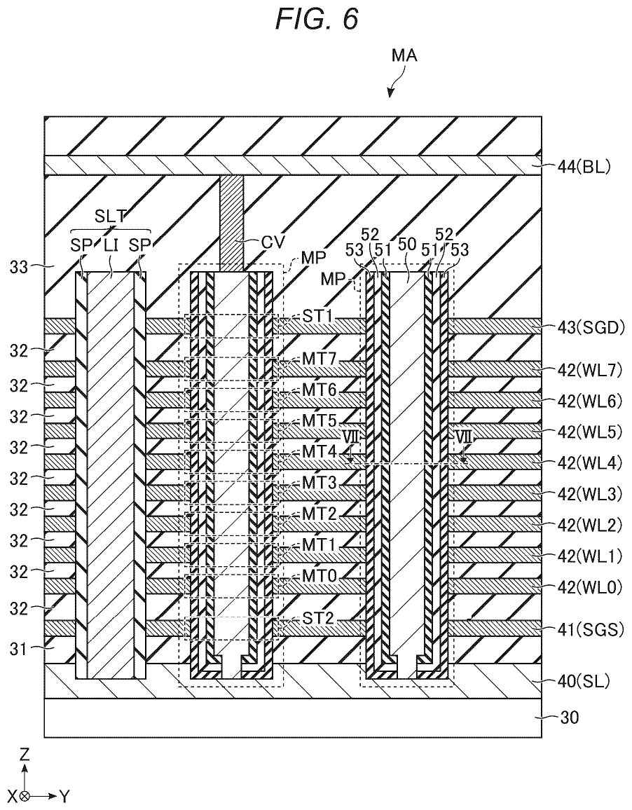

An example of a cross-sectional structure of the memory region MA in the semiconductor memory device 10 according to the first embodiment will be described with reference to FIG. 6. FIG. 6 is a cross-sectional view illustrating the memory region MA in the memory cell array 11 of the semiconductor memory device 10. FIG. 6 illustrates a portion of a cross-section along the Y direction including the memory pillar MP and the slit SLT.

The memory region MA includes the substrate 30, insulating layers 31 to 33, conductive layers 40 to 44, the memory pillar MP, the contact plug CV, and the slit SLT.

The conductive layer 40 is provided on the substrate 30. For example, the conductive layer 40 is formed in a plate shape extending along an XY plane and is used as the source line SL. The conductive layer 40 contains, for example, phosphorus-doped polysilicon.

The insulating layer 31 is provided on the conductive layer 40. The conductive layer 41 is provided on the insulating layer 31. For example, the conductive layer 41 is formed in a plate shape extending along the XY plane and is used as the select gate line SGS. The conductive layer 41 contains, for example, tungsten or phosphorus-doped polysilicon. The select gate line SGS may be configured with a plurality of conductive layers 41. When the select gate line SGS is configured with the plurality of conductive layers 41, the plurality of conductive layers 41 may each be configured with different conductors.

The insulating layers 32 and the conductive layers 42 are alternately stacked on the conductive layer 41. For example, a plurality of conductive layers 42 are each formed in a plate shape extending along the XY plane. The plurality of conductive layers 42 are used as the word lines WL0 to WL7 in order from the conductive layer 40 side. The conductive layers 42 contain, for example, tungsten. The insulating layers 32 are, for example, oxide layers containing silicon oxide (SiO₂).

The conductive layer 43 is provided on the uppermost insulating layer 32. For example, the conductive layer 43 is formed in a plate shape extending along the XY plane and is used as the select gate line SGD. The select gate line SGD may be configured with a plurality of conductive layers 43. The conductive layer 43 contains, for example, tungsten.

The insulating layer 33 is provided on the conductive layer 43. The conductive layer 44 is provided on the insulating layer 33. For example, the conductive layer 44 is formed in a linear shape extending in the Y direction and is used as the bit line BL. In a region (not illustrated), a plurality of conductive layers 44 are arranged in the X direction. The conductive layer 44 contains, for example, copper.

Each memory pillar MP extends in the Z direction. Each memory pillar MP penetrates the insulating layers 31 and 32 and the conductive layers 41 to 43. A lower portion of the memory pillar MP comes into contact with the conductive layer 40. An upper portion of the memory pillar MP reaches the insulating layer 33.

Each memory pillar MP includes, for example, a semiconductor layer 50, a tunnel insulating layer (also referred to as a tunnel insulating film) 51, a charge storage layer (for example, an insulating layer) 52, and a block insulating layer 53.

The semiconductor layer 50, the tunnel insulating layer 51, the charge storage layer 52, and the block insulating layer 53 extend in the Z direction. For example, a lower end of the semiconductor layer 50 comes into contact with the conductive layer 40. An upper end of the semiconductor layer 50 is provided in a layer including the insulating layer 33. The tunnel insulating layer 51 is disposed on a side surface of the semiconductor layer 50. The charge storage layer 52 is disposed on a side surface of the tunnel insulating layer 51. The block insulating layer 53 is disposed on a side surface of the charge storage layer 52. The memory pillar MP may have a structure in which a core insulating layer is provided inside the semiconductor layer 50.

A portion in which the memory pillar MP intersects the conductive layer 41 (that is, the select gate line SGS) functions as the select transistor ST2. Portions in which the memory pillar MP intersects the plurality of conductive layers 42 (that is, the word lines WL) function as the memory cell transistors MT0 to MT7. A portion in which the memory pillar MP intersects the conductive layer 43 (that is, the select gate line SGD) functions as the select transistor ST1.

The semiconductor layer 50 functions as a channel layer of each of the memory cell transistors MT0 to MT7 and the select transistors ST1 and ST2. Inside the semiconductor layer 50, a current path of the NAND string NS is formed. The charge storage layer 52 functions as a layer that stores charge of the memory cell transistor MT.

The columnar contact plug CV is provided on the semiconductor layer 50 of each memory pillar MP. In the illustrated region, the contact plug CV corresponding to one memory pillar MP of two memory pillars MP is illustrated. The memory pillar MP not connected to the contact plug CV in the above region is connected to the contact plug CV in another region (not illustrated). One conductive layer 44 (that is, the bit line BL) comes into contact on the contact plug CV.

The slit SLT includes, for example, a spacer SP and a contact LI. The slit SLT is formed in a plate shape of which at least a portion extends along an XZ plane, the slit SLT dividing the insulating layers 31 and 32 and the conductive layers 41 to 43. For example, a lower end of the slit SLT comes into contact with the conductive layer 40. An upper end of the slit SLT is provided in the layer including the insulating layer 33. In the slit SLT, at least a portion of the contact LI extends in the X direction. The spacer SP is provided on a side surface of the contact LI. The contact LI is separated and insulated from the plurality of conductive layers 41 to 43 by the spacer SP.

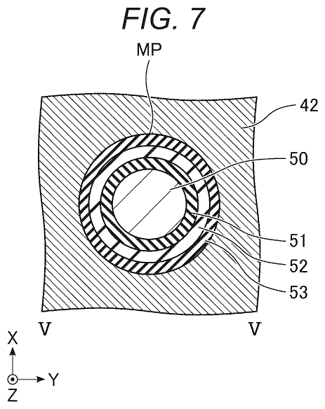

Next, a cross-sectional structure of the memory pillar MP provided in the memory region MA will be described. FIG. 7 illustrates a cross-section along a line VII-VII of FIG. 6 and illustrates a cross-section of the memory pillar MP in a layer parallel to the surface of the substrate 30 and including the conductive layer 42.

The memory pillar MP includes, for example, the semiconductor layer 50, the tunnel insulating layer 51, the charge storage layer 52, and the block insulating layer 53 as described above. Specifically, the semiconductor layer 50 is provided in, for example, a center portion of the memory pillar MP. The tunnel insulating layer 51 surrounds a side surface of the semiconductor layer 50. The charge storage layer 52 surrounds a side surface of the tunnel insulating layer 51. The block insulating layer 53 surrounds a side surface of the charge storage layer 52. The conductive layer 42 surrounds a side surface of the block insulating layer 53. The memory pillar MP may have a structure in which a core insulating layer is provided inside the semiconductor layer 50.

The tunnel insulating layer 51 functions as a voltage barrier when charges are injected from the semiconductor layer 50 to the charge storage layer 52 or when charge stored in the charge storage layer 52 is diffused to the semiconductor layer 50. The tunnel insulating layer 51 contains, for example, silicon oxide (SiO₂).

The charge storage layer 52 has a function of storing charge injected from the semiconductor layer 50 in the memory cell transistors MT0 to MT7. The charge storage layer 52 contains, for example, silicon nitride (SiN).

The block insulating layer 53 prevents charge stored in the charge storage layer 52 from being diffused to the conductive layer 42 (the word line WL). The block insulating layer 53 contains, for example, aluminum oxide, silicon oxide, and silicon nitride.

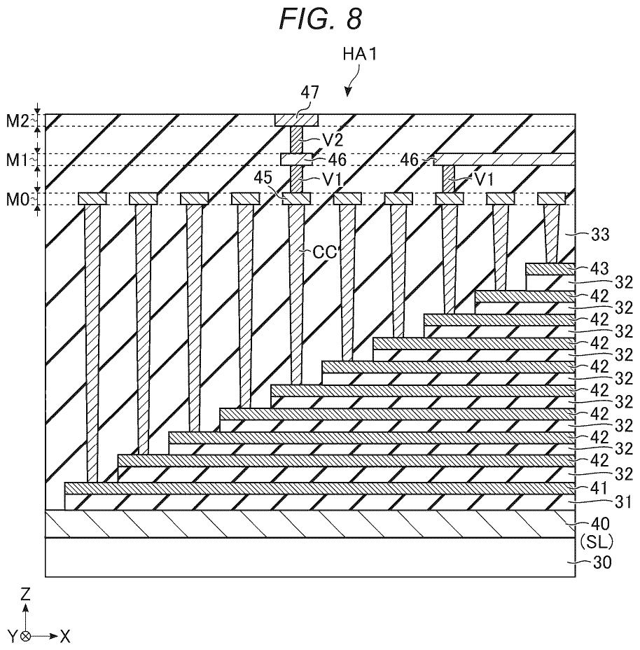

Next, an example of a cross-sectional structure of the lead region HA1 in the semiconductor memory device 10 according to the first embodiment will be described with reference to FIG. 8. FIG. 8 is a cross-sectional view illustrating the lead region HA1 in the memory cell array 11 of the semiconductor memory device 10. FIG. 8 illustrates a cross-section along the X direction of the lead region HA1 and a region corresponding to an even block BLK in FIG. 4.

In the lead region HA1, an end portion of each of the select gate line SGS (the conductive layer 41), the word lines WL0 to WL7 (the conductive layers 42), and the select gate line SGD (the conductive layer 43) is provided in a step shape. In the lead region HA1, for example, the contact plugs CC, contact plugs V1 and V2, and conductive layers 45, 46, and 47 are provided.

Specifically, the conductive layer 41 includes a terrace portion that does not overlap with the upper conductive layers 42 and 43 in the Z direction. Each conductive layer 42 includes a terrace portion that does not overlap with the upper conductive layers 42 and 43 in the Z direction. The conductive layer 43 includes a terrace portion in the Z direction. The plurality of contact plugs CC are provided above the terrace portions of each of the conductive layers 41 to 43.

For example, the conductive layer 45 is provided on each contact plug CC. The conductive layer 45 is provided in a wiring layer M0. The contact plug V1 is provided on the conductive layer 45. The conductive layer 46 is provided on the contact plug V1. The conductive layer 46 is provided in a wiring layer M1. The contact plug V2 is provided on the conductive layer 46. The conductive layer 47 is provided on the contact plug V2. The conductive layer 47 is provided in a wiring layer M2.

FIG. 6 illustrates only pairs including the contact plugs V1 and V2 and the conductive layers 46 and 47 provided in the conductive layer 45 corresponding to the word line WL3. The pairs including the contact plugs V1 and V2 and the conductive layers 46 and 47 are connected to other conductive layers 45 in another region (not illustrated).

A structure in a region corresponding to the lead region HA1 and an odd block BLK is similar to a structure in which the contact plugs CC are omitted in the structure illustrated in FIG. 8. A structure in a region corresponding to the lead region HA2 and an odd block BLK is similar to a structure in which the structure illustrated in FIG. 8 is reversed using a YZ plane as a symmetric plane.

### 1.2.3. Structure of Word Line and Memory Pillar

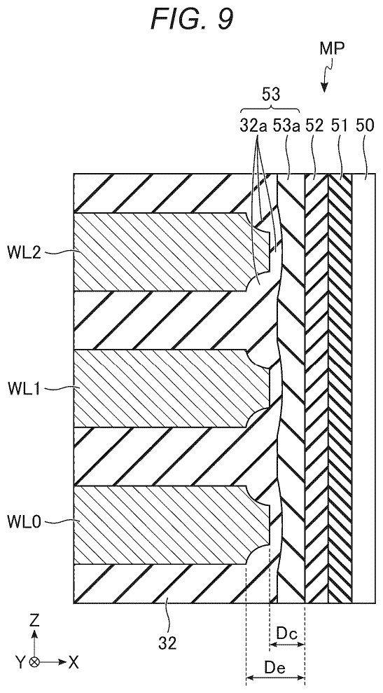

Next, a structure of the word line WL and the memory pillar MP in the semiconductor memory device 10 according to the first embodiment will be described in detail with reference to FIG. 9. FIG. 9 is a cross-sectional view illustrating a structure of the word line WL and the memory pillar MP in the memory cell array 11 of the semiconductor memory device 10. FIG. 9 illustrates a portion of a cross-section of the word line WL and the memory pillar MP along the XZ plane. Here, the word lines WL0, WL1, and WL2 are illustrated as an example, but other word lines also have the same structure.

As described above, the word lines WL0, WL1, and WL2 are stacked on the substrate 30 with the insulating layer 32 interposed therebetween in the Z direction. The memory pillar MP penetrates the word lines WL0, WL1, and WL2 in the Z direction. The memory pillar MP includes the block insulating layer 53, the charge storage layer 52, the tunnel insulating layer 51, and the semiconductor layer 50. The block insulating layer 53, the charge storage layer 52, the tunnel insulating layer 51, and the semiconductor layer 50 extend in the Z direction.

An end surface of the word line WL0 along the Z direction includes a center portion, an end portion on the upper side (hereinafter referred to as an upper end portion), and an end portion on the lower side (hereinafter referred to as a lower end portion). The upper end portion is disposed at an upper end portion of the end surface in the Z direction. The lower end portion is disposed at a lower end portion of the end surface in the Z direction. The center portion is disposed near the center interposed between the upper end portion and the lower end portion of the end surface in the Z direction. The upper end portion and the lower end portion on the end surface of the word line WL0 has, for example, a recessed shape or a rounded shape.

The block insulating layer 53, the charge storage layer 52, the tunnel insulating layer 51, and the semiconductor layer 50 are provided in order in the X direction on the end surface of the word line WL0. The block insulating layer 53 includes, for example, an insulating layer (for example, a silicon oxide layer) 32a and an insulating layer 53a. That is, the block insulating layer 53 is an insulating layer between the end surface of the word line WL0 and the charge storage layer 52. That is, the block insulating layer 53 is a layer in which the insulating layers 32a and 53a are combined.

Here, a thickness of the block insulating layer 53 facing the upper end portion or the lower end portion on the end surface of the word line WL0 is referred to as a first thickness De. A thickness of the block insulating layer 53 facing the center portion on the end surface of the word line WL0 is referred to as a second thickness Dc. The first thickness De is different from the second thickness Dc in that the first thickness De is thicker than the second thickness Dc. The first thickness De corresponds to a distance from the upper end portion or the lower end portion on the end surface of the word line WL0 to the charge storage layer 52, and the second thickness Dc corresponds to a distance from the center portion on the end surface of the word line WL0 to the charge storage layer 52.

The charge storage layer 52, the tunnel insulating layer 51, and the semiconductor layer 50 facing the end surface of the word line WL0 is formed in a linear shape in the Z direction. In other words, the charge storage layer 52, the tunnel insulating layer 51, and the semiconductor layer 50 facing the end surface of the word line WL0 do not protrude toward the word line WL0 side in the X direction.

The structures of the word line WL0 and the memory pillar MP near the word line WL0 are described above. The same applies to the structures of the word lines WL1 and WL2 and the memory pillar MP near the word lines.

### 1.3. Method of Manufacturing Word Line and Memory Pillar

Next, a method of manufacturing the word line WL and the memory pillar MP in the semiconductor memory device 10 according to the first embodiment will be described.

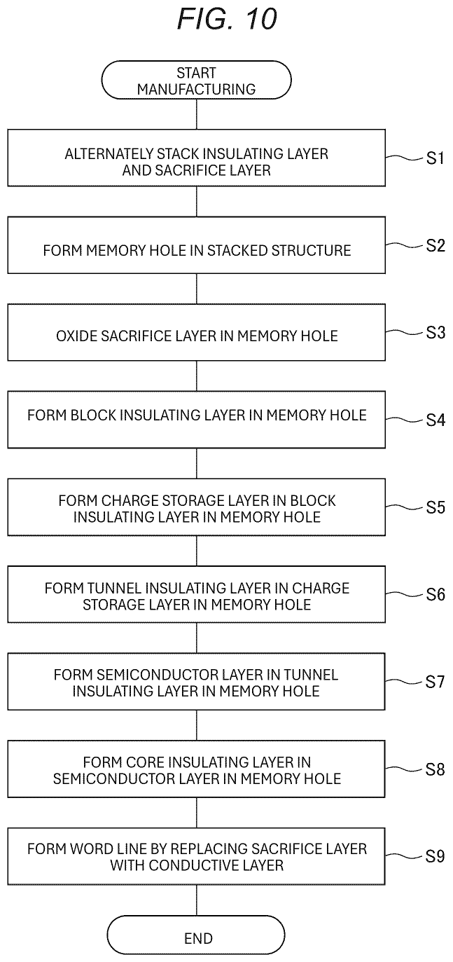

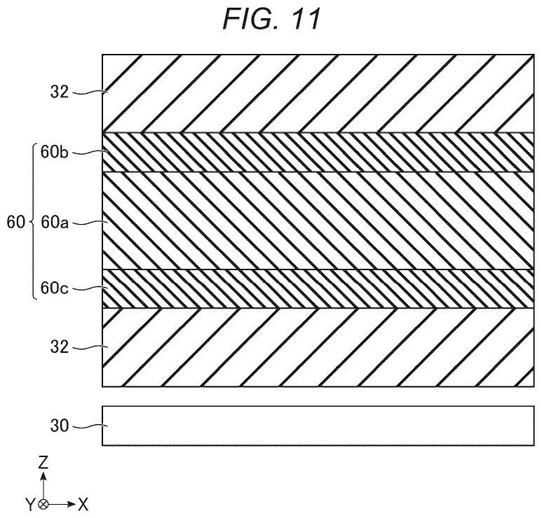

FIG. 10 is a flowchart illustrating the method of manufacturing the word line WL and the memory pillar MP in the semiconductor memory device 10. FIGS. 11 to 19 are cross-sectional views illustrating the method of manufacturing the word line WL and the memory pillar MP in the semiconductor memory device 10. Here, a process of manufacturing one word line WL and the memory pillar MP will be extracted and described.

First, as illustrated in FIG. 11, the insulating layer (for example, an oxide layer) 32 and the sacrifice layer (for example, a nitride layer) 60 are alternately stacked on the substrate 30 (S1). The sacrifice layer 60 includes a sacrifice layer 60a, and sacrifice layers 60b and 60c having different film material from the sacrifice layer 60. Selectivity during etching exists between the insulating layer 32 and the sacrifice layers 60a, 60b, and 60c. That is, during etching, the sacrifice layers 60a, 60b, and 60c can be selectively etched relative to the insulating layer 32. The sacrifice layers 60b and 60c are also more easily oxidized than the sacrifice layer 60a. It should be noted that, in the following drawings, description of the substrate 30 will be omitted.

The insulating layer 32 contains, for example, silicon oxide (SiO₂). The sacrifice layer 60a contains, for example, silicon nitride (SiN). The sacrifice layers 60b and 60c contain, for example, silicon oxynitride (SiON).

Specifically, for example, the silicon oxide layer 32 is formed on the substrate 30 by chemical vapor deposition (CVD). Subsequently, for example, a silicon oxynitride layer 60c is formed on the silicon oxide layer 32 and a silicon nitride layer 60a is formed on the silicon oxynitride layer 60c by CVD. Then, a silicon oxynitride layer 60b is formed on the silicon nitride layer 60a. Subsequently, the silicon oxide layer 32 is formed on the silicon oxynitride layer 60b. As such, the silicon oxide layer 32, the silicon oxynitride layer 60c, the silicon nitride layer 60a, and the silicon oxynitride layer 60b are formed repeatedly in order, thereby forming a stacked structure.

Here, the silicon oxide layer is used as the insulating layer 32, the silicon oxynitride layer is used as the sacrifice layer 60a, and the silicon oxynitride layers are used as the sacrifice layers 60b and 60c, but the embodiment is not limited thereto. The embodiment is not limited as long as selectivity during etching exists between the insulating layer 32 and the sacrifice layers 60a, 60b, and 60c. That is, during the etching, the embodiment is not limited as long as the sacrifice layers 60a, 60b, and 60c are selectively etched relative to the insulating layer 32, and other layers having such characteristics may be used. The embodiment is not limited as long as the sacrifice layers 60b and 60c are layers more easily oxidized than the sacrifice layer 60a, and such other layers may be used.

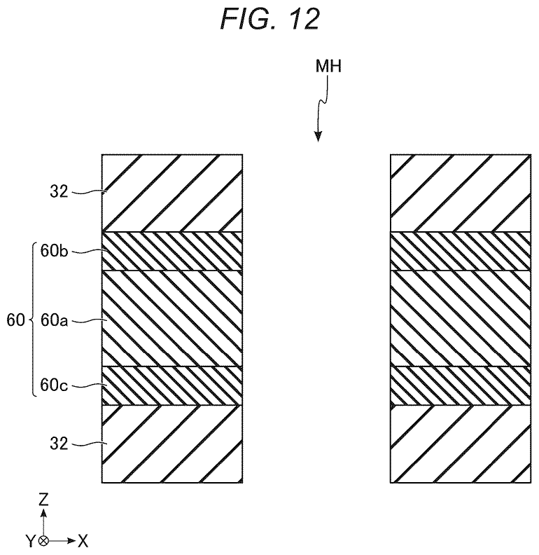

Subsequently, as illustrated in FIG. 12, a hole MH for providing the memory pillar MP in the stacked structure illustrated in FIG. 10 is formed (S2). Hereinafter, the hole MH is referred to as a memory hole.

Specifically, the memory hole MH is formed in the stacked structure in which the silicon oxide layer 32, the silicon oxynitride layer 60c, the silicon nitride layer 60a, and the silicon oxynitride layer 60b are stacked.

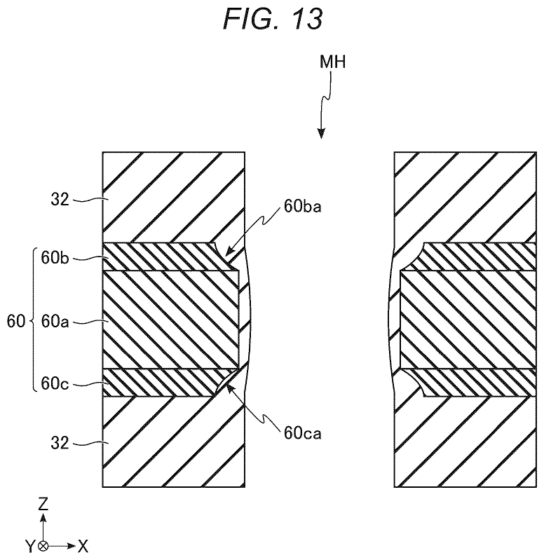

Subsequently, as illustrated in FIG. 13, the silicon oxynitride layers 60b and 60c are oxidized to form a recessed shape in the silicon oxynitride layers 60b and 60c (S3).

Specifically, for example, the silicon oxynitride layers 60b and 60c and the silicon nitride layer 60a are oxidized by a thermal oxidation method. The silicon oxynitride layers 60b and 60c are layers that are more easily oxidized than the silicon nitride layer 60a. Therefore, oxidation is progressed from an interface between the silicon oxide layer 32 and the silicon oxynitride layer 60b toward inside of the silicon oxynitride layer 60b, so that a portion of the silicon oxynitride layer 60b is changed to silicon oxide. Further, oxidation is progressed from an inner surface of the memory hole MH toward inside of the silicon oxynitride layer 60b, so that a portion of the silicon oxynitride layer 60b is changed to silicon oxide. Accordingly, oxidation of a corner of the silicon oxynitride layer 60b that comes into contact with the silicon oxide layer 32 and is exposed to the inner surface of the memory hole MH is progressed rapidly. As a result, a recessed shape 60ba illustrated in FIG. 13 is formed in a corner of an upper surface of the silicon oxynitride layer 60b.

Similarly, oxidation of a corner of a lower surface of the silicon oxynitride layer 60c is progressed rapidly, so that a recessed shape 60ca is formed in the corner of the lower surface of the silicon oxynitride layer 60c. As such, a silicon oxide layer 32a is formed in the silicon oxynitride layers 60b and 60c and the silicon nitride layer 60a on the inner surface of the memory hole MH.

Depending on film materials or oxidation conditions of the silicon oxynitride layers 60b and 60c, rounded shapes may be formed in the corners of the silicon oxynitride layers 60b and 60c.

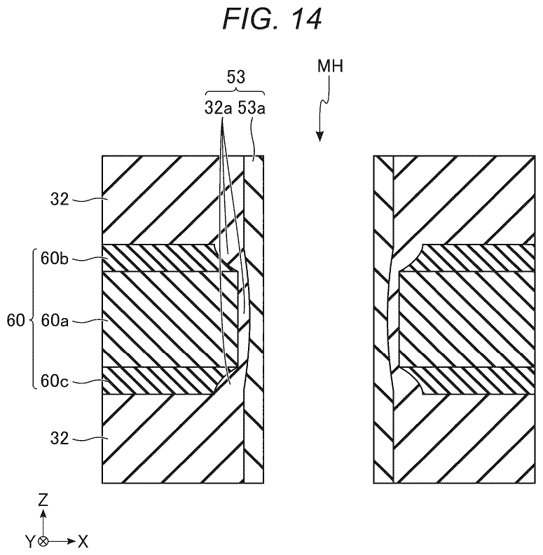

Subsequently, as illustrated in FIG. 14, a silicon oxide layer 53a is formed in the silicon oxide layers 32a and 32 on the inner surface of the memory hole MH (S4).

Specifically, the silicon oxide layer 53a is formed in the silicon oxide layer 32 including the silicon oxide layer 32a on the inner surface of the memory hole MH by, for example, atomic layer deposition (ALD). The silicon oxide layers 32a and 53a are formed on side surfaces of the silicon oxynitride layers 60b and 60c and the silicon nitride layer 60a to function as block insulating layers.

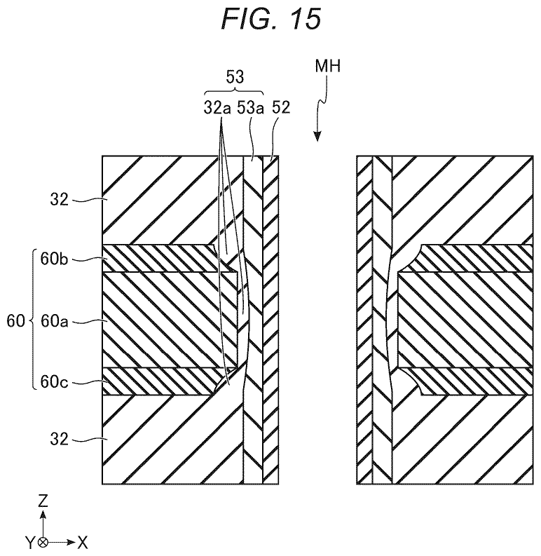

Subsequently, as illustrated in FIG. 15, the charge storage layer 52 is formed in the silicon oxide layer 53a on the inner surface of the memory hole MH (S5). Specifically, the charge storage layer 52 is formed on a side surface of the silicon oxide layer 53a on the inner surface of the memory hole MH by, for example, ALD.

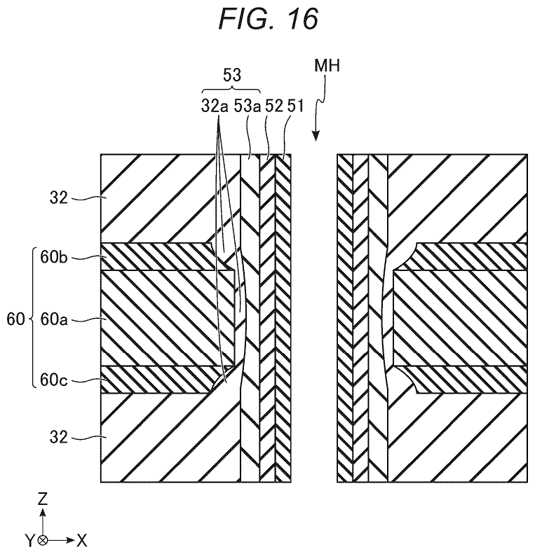

Subsequently, as illustrated in FIG. 16, the tunnel insulating layer 51 is formed in the charge storage layer 52 on the inner surface of the memory hole MH (S6). Specifically, the tunnel insulating layer 51 is formed on a side surface of the charge storage layer 52 on the inner surface of the memory hole MH by, for example, ALD.

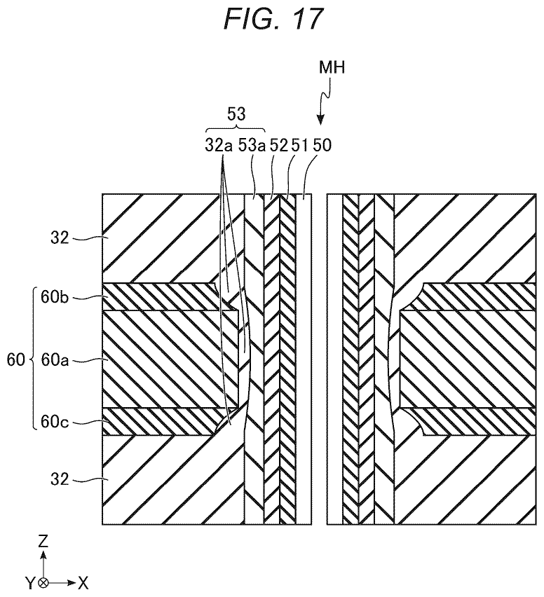

Subsequently, as illustrated in FIG. 17, the semiconductor layer 50 is formed in the tunnel insulating layer 51 on the inner surface of the memory hole MH (S7).

Specifically, for example, an amorphous silicon layer is formed on a side surface of the tunnel insulating layer 51 on the inner surface of the memory hole MH by, for example, ALD. Thereafter, the amorphous silicon layer is crystalized by thermal processing to form the polycrystalline silicon semiconductor layer 50.

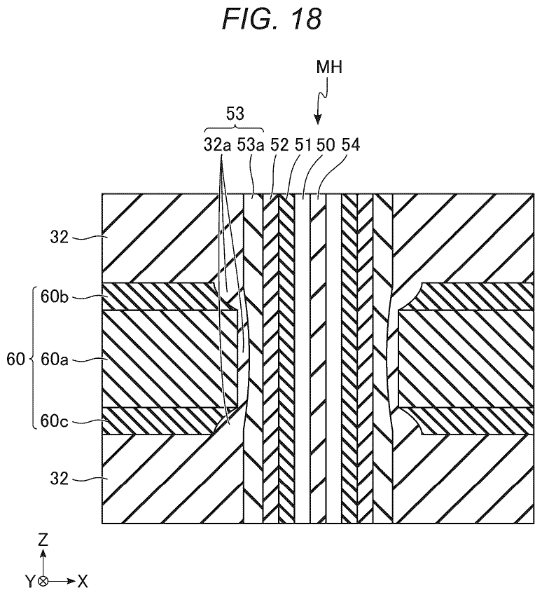

Subsequently, as illustrated in FIG. 18, a core insulating layer 54 is formed in the semiconductor layer 50 on the inner surface of the memory hole MH (S8). Specifically, the core insulating layer 54 is formed in a space surrounded by the semiconductor layer 50 on the inner surface of the memory hole MH by, for example, ALD.

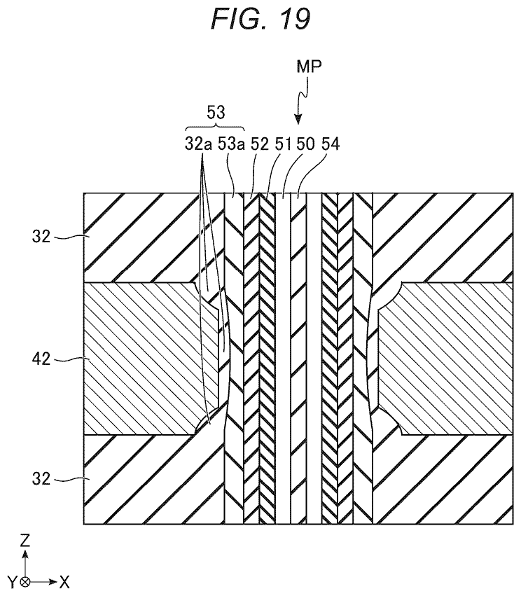

Subsequently, as illustrated in FIG. 19, the sacrifice layer 60 is replaced with the conductive layer 42 to form the word line WL (S9).

Specifically, for example, the silicon nitride layer 60a and the silicon oxynitride layers 60b and 60c are removed by wet etching. Then, the conductive layer 42 is formed by, for example, ALD, in a space from which the silicon nitride layer 60a and the silicon oxynitride layers 60b and 60c are removed. The conductive layer 42 contains, for example, tungsten.

As such, manufacturing of the word line WL and the memory pillar MP ends.

### 1.4. Structures of Memory Hole Opening Region and Non-Opening Region

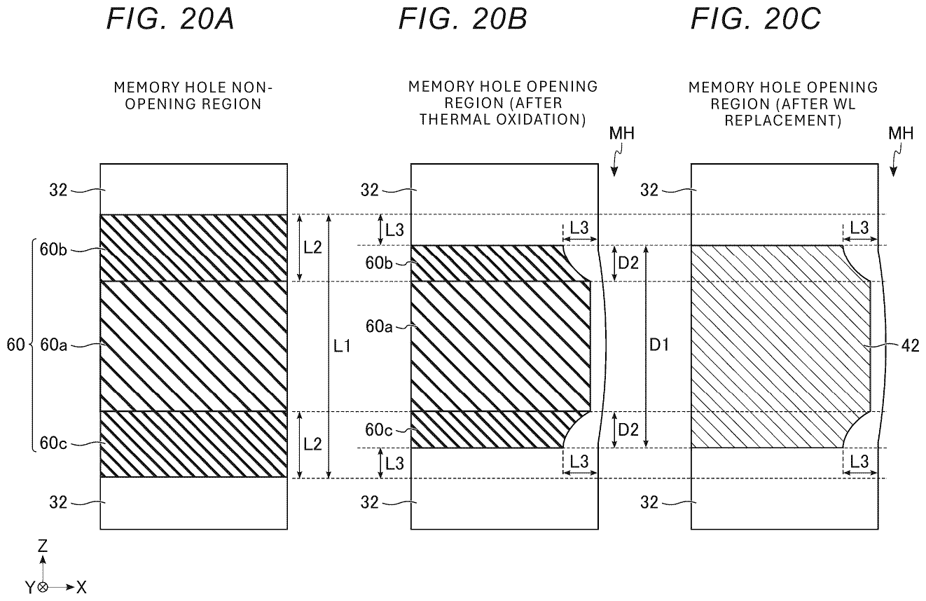

Next, structures of a region where the sacrifice layer 60 is replaced with the word line WL (hereinafter referred to as a memory hole opening region) and a region where the sacrifice layer 60 is not replaced with the word line WL (hereinafter referred to as a memory hole non-opening region) will be compared to each other in description with reference to FIG. 20. (A) of FIG. 20 illustrates a stacked structure of the memory hole non-opening region in the semiconductor memory device 10. (B) and (C) of FIG. 20 illustrate a stacked structure of the memory hole opening region in the semiconductor memory device 10. Here, the structures corresponding to one word line WL are extracted.

In the semiconductor memory device 10, the memory hole opening region and the memory hole non-opening region are provided. The memory hole opening region is a region where the memory hole MH for forming the memory pillar MP is opened and thermal processing is performed to replace the sacrifice layer 60 with the conductive layer 42. The memory hole non-opening region is a region where the memory hole MH is not opened, oxidization of the sacrifice layer 60 is not progressed excessively even when thermal processing is performed, and the sacrifice layer 60 is not replaced with the conductive layer 42.

In the memory hole non-opening region, oxidation is not progressed excessively and the sacrifice layer 60 is not replaced with the conductive layer 42. Therefore, in the memory hole non-opening region, almost all of the stacked sacrifice layers 60a, 60b, and 60c remains. Here, as illustrated in (A) of FIG. 20, a thickness in the Z direction of the combined sacrifice layers 60a, 60b, and 60c disposed in the memory hole non-opening region is referred to as L1, and a thickness in the Z direction of each of the sacrifice layers 60b and 60c is referred to as L2.

In the memory hole opening region, oxidation of the sacrifice layer 60b is progressed when the memory hole MH is opened and thermal oxidation is performed. Here, as illustrated in (B) of FIG. 20, an oxidation amount of an upper surface and a side surface of the sacrifice layer 60b is referred to as L3. An oxidation amount of a lower surface and the side surface of the sacrifice layer 60c is also referred to as L3. A thickness of the combined sacrifice layers 60a, 60b, and 60c after thermal oxidation is referred to as D1, and a thickness of each of the sacrifice layers 60b and 60c is referred to as D2.

Thereafter, the sacrifice layer 60 is replaced with the conductive layer 42. Here, a thickness of the conductive layer 42, that is, a thickness of the word line WL is the same as the combined thickness D1 of the sacrifice layers 60a, 60b, and 60c.

The thickness D2 and the oxidation amount L3 are set when designing the shape of the word line WL. A combined thickness of the thickness D2 and the oxidation amount L3 is the thickness L2 of the sacrifice layer 60b (or 60c) in the memory hole non-opening region. In the above-described structure, the thickness D1 of the word line WL is thinner than the thickness L1 of the sacrifice layer 60 in the memory hole non-opening region.

As illustrated in FIGS. 3 and 5, the memory hole non-opening region is provided mainly in the dummy region DR, the TEG region TR, the inter-plane region PP, the edge region PR, and the contact region C4T.

### 1.5. Advantages of First Embodiment

According to the first embodiment, it is possible to provide a semiconductor memory device capable of improving characteristics of a memory cell and a manufacturing method thereof.

Hereinafter, advantages of the first embodiment will be described.

For example, in the semiconductor memory device, the plurality of stacked word lines may be formed by forming a stacked structure in which an oxide layer and a nitride layer are alternately stacked on a substrate, and then replacing the nitride layer with a conductive layer. In recent years, the word lines are stacked highly, and thus it is necessary to reduce a stacking interval between the stacked word lines (or a stacking interval of an oxide layer and a nitride layer) (hereinafter referred to as a stacking pitch). However, reduction in the stacking pitch between the word lines may deteriorate characteristic of a memory cell.

In the first embodiment, in a cross-section obtained by cutting the word line WL and the memory pillar MP by a plane along the X direction and the Z direction, an end surface of the word line WL along the Z direction includes a center portion and an end portion. The first thickness of the block insulating layer 53 facing the end portion on the end surface of the word line WL is different from the second thickness of the block insulating layer 53 facing the center portion on the end surface of the word line WL. The charge storage layer 52, the tunnel insulating layer 51, and the semiconductor layer 50 facing the end surface of the word line WL are provided in a straight linear in the Z direction. Accordingly, by alleviating concentration of charge density in the charge storage layer disposed near the end portion (or the corner) of the word line WL, it is possible to reduce occurrence of phenomena such as interference between cells adjacent to each other and movement of charge remaining in the charge storage layer of memory cells adjacent to each other to the charge storage layer corresponding to the memory cell. As a result, it is possible to improve characteristics of the memory cell.

By alleviating concentration of charge density in the charge storage layer disposed near the end portion of the word line WL, it is possible to reduce occurrence of phenomena in which charge stored in the charge storage layer is diffused to the word line WL and improve a problem such as insufficient erasure during an erase operation.

By forming a recessed shape in the end portion (the corner) on the end surface of the word line WL that comes into contact with the block insulating layer, it is possible to increase a distance between the corners of the word lines WL adjacent to each other. In other words, in the first word line and the second word line adjacent to each other, it is possible to increase an interval between the corner of the first word line and the corner of the second word line. Accordingly, it is also possible to reduce the stacking interval (the stacking pitch) between the stacked word lines. Accordingly, it is possible to achieve high stacking of the word lines WL.

For example, in a method of manufacturing the semiconductor memory device, after the memory hole is formed, process of forming the silicon nitride layer, oxidizing the silicon nitride layer by a thermal oxidation method, and forming the silicon oxide layer may be executed.

Meanwhile, in the manufacturing method according to the first embodiment, after the memory hole MH is formed, a silicon nitride layer as a sacrifice layer of the word line WL is oxidized by a thermal oxidation method without forming a silicon nitride layer, and then a silicon oxide layer is formed. Since formation of the silicon nitride layer after formation of the memory hole MH can be reduced, the manufacturing process can be simplified.

Similarly, since formation of the silicon nitride layer after formation of the memory hole MH can be reduced, reduction of an inner diameter of the memory hole MH can be prevented. Thus, it is possible to improve a process of forming the semiconductor layer and improve embeddability of the charge storage layer, the tunnel insulating layer, and the semiconductor layer in the memory hole MH.

Since the silicon nitride layer as a sacrifice layer of the word line WL is oxidized after formation of the memory hole MH, warping that protrudes upward from the substrate due to stress is caused. In a subsequent process, thermal processing is executed a plurality of times, so that warping that protrudes downward from the substrate may be caused. In the embodiment, by performing thermal processing in the earlier process of causing warping to protrude upward from the substrate, it is possible to prevent occurrence of warping that protrudes downward from the substrate in a subsequent process.

As described above, according to the semiconductor memory device and the manufacturing process thereof according to the first embodiment, it is possible to improve characteristics of the memory cell.

### 2. Second Embodiment

A semiconductor memory device according to a second embodiment will be described. In the second embodiment, an example in which only an end portion on the upper side (hereinafter referred to as an upper end portion) on the end surface of the word line WL has a recessed shape will be described. In the second embodiment, differences from the first embodiment will be described mainly.

### 2.1. Structure of Word Line and Memory Pillar

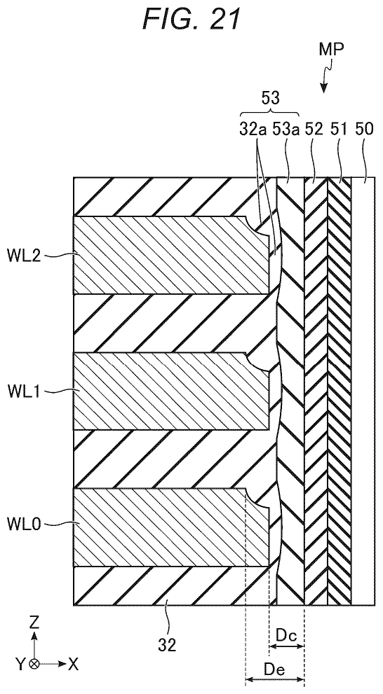

FIG. 21 is a cross-sectional view illustrating a structure of the word line WL and the memory pillar MP in the memory cell array 11 of the semiconductor memory device 10 according to the second embodiment. FIG. 21 illustrates a portion of a cross-section of the word line WL and the memory pillar MP along the XZ plane.

The end surface of the word line WL0 along the Z direction includes a center portion, an upper end portion, and a lower end portion. The upper end portion on the end surface of the word line WL0 has, for example, a recessed shape or a rounded shape. Meanwhile, the lower end portion on the end surface of the word line WL0 has a recessed shape or a rounded shape without being deformed intentionally.

Here, as illustrated in FIG. 21, a thickness of the block insulating layer 53 facing the upper end portion on the end surface of the word line WL0 is referred to as a first thickness De, and a thickness of the block insulating layer 53 facing the center portion on the end surface of the word line WL0 is referred to as a second thickness Dc. The first thickness De is different from the second thickness Dc in that the first thickness De is thicker than the second thickness Dc. It should be noted that the first thickness De corresponds to a distance from the upper end portion on the end surface of the word line WL0 to the charge storage layer 52, and the second thickness Dc corresponds to a distance from the center portion on the end surface of the word line WL0 to the charge storage layer 52.

The charge storage layer 52, the tunnel insulating layer 51, and the semiconductor layer 50 facing the end surface of the word line WL0 is formed in a linear shape in the Z direction. In other words, the charge storage layer 52, the tunnel insulating layer 51, and the semiconductor layer 50 facing the end surface of the word line WL0 do not protrude toward the word line WL0 side in the X direction.

The structures of the word line WL0 and the memory pillar MP near the word line WL0 are described above. The same applies to the structures of the word lines WL1 and WL2 and the memory pillar MP near the word lines.

### 2.2. Method of Manufacturing Word Line and Memory Pillar

Next, a method of manufacturing the word line WL and the memory pillar MP in the semiconductor memory device 10 according to the second embodiment will be described.

In the manufacturing method according to the first embodiment, the silicon oxide layer 32, the silicon oxynitride layer 60c, the silicon nitride layer 60a, and the silicon oxynitride layer 60b are stacked in order on the substrate 30. In the second embodiment, the silicon oxide layer 32, the silicon nitride layer 60a, and the silicon oxynitride layer 60b are stacked in order on the substrate 30 without forming the silicon oxynitride layer 60c. Other processes are similar to those of the manufacturing method according to the first embodiment.

### 2.3. Structures of Memory Hole Opening Region and Non-Opening Region

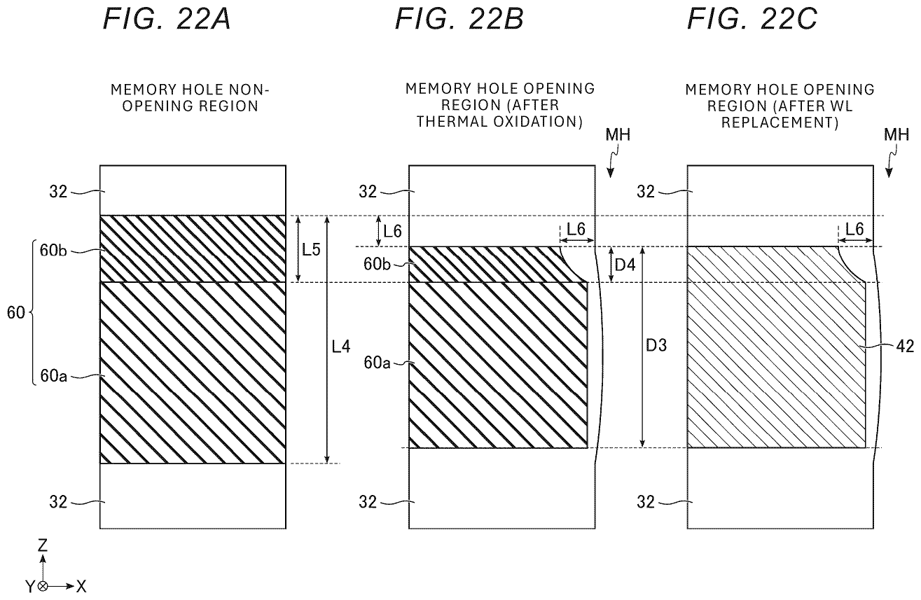

Next, structures of a memory hole opening region and a memory hole non-opening region will be compared to each other in description with reference to FIG. 22. (A) of FIG. 22 illustrates a stacked structure of the memory hole non-opening region in the semiconductor memory device 10. (B) and (C) of FIG. 22 illustrate a stacked structure of the memory hole opening region in the semiconductor memory device 10. Here, the structures corresponding to one word line WL are extracted.

In the memory hole non-opening region, oxidation is not progressed excessively and the sacrifice layer 60 is not replaced with the conductive layer 42. Therefore, in the memory hole non-opening region, almost all of the stacked sacrifice layers 60a and 60b remains. Here, as illustrated in (A) of FIG. 22, a thickness in the Z direction of the combined sacrifice layers 60a and 60b disposed in the memory hole non-opening region is referred to as L4, and a thickness in the Z direction of the sacrifice layer 60b is referred to as L5.

In the memory hole opening region, oxidation of the sacrifice layer 60b is progressed when the memory hole MH is opened and thermal oxidation is performed. Here, as illustrated in (B) of FIG. 22, an oxidation amount of the upper surface and the side surface of the sacrifice layer 60b is referred to as L6. A thickness of the combined sacrifice layers 60a and 60b after thermal oxidation is referred to as D3, and a thickness of the sacrifice layer 60b is referred to as D4.

Thereafter, the sacrifice layer 60 is replaced with the conductive layer 42. Here, a thickness of the conductive layer 42, that is, a thickness of the word line WL is the same as the combined thickness D3 of the sacrifice layers 60a and 60b.

The thickness D4 and the oxidation amount L6 are set when designing the shape of the word line WL. A combined thickness of the thickness D4 and the oxidation amount L6 is the thickness L5 of the sacrifice layer 60b in the memory hole non-opening region. In the above-described structure, the thickness D3 of the word line WL is thinner than the thickness L4 of the sacrifice layer 60 in the memory hole non-opening region.

As illustrated in FIGS. 3 and 5, the memory hole non-opening region is provided mainly in the dummy region DR, the TEG region TR, the inter-plane region PP, the edge region PR, and the contact region C4T.

### 2.4. Advantages of Second Embodiment

According to the second embodiment, as in the first embodiment, it is possible to provide a semiconductor memory device capable of improving characteristics of a memory cell and a manufacturing method thereof.

In the second embodiment, the recessed shape is formed only in the upper end portion on the end surface of the word line WL. In such a structure, it is possible to improve characteristics of the memory cell. Other advantages are similar to those of the first embodiment.

### 3. Third Embodiment

A semiconductor memory device according to a third embodiment will be described. In the third embodiment, an example in which only the end portion on the lower side (hereinafter referred to as a lower end portion) on the end surface of the word line WL has a recessed shape will be described. In the third embodiment, differences from the first embodiment will be described mainly.

### 3.1. Structure of Word Line and Memory Pillar

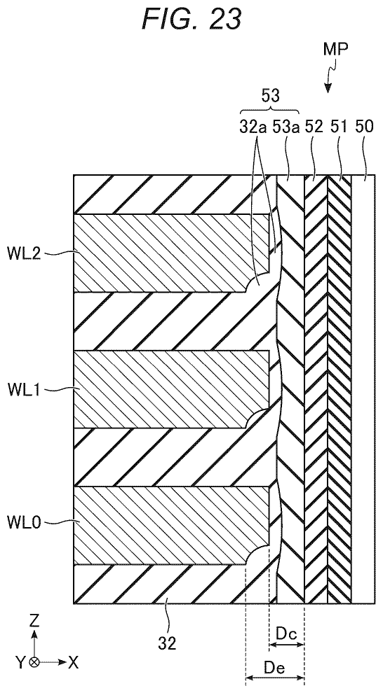

FIG. 23 is a cross-sectional view illustrating a structure of the word line WL and the memory pillar MP in the semiconductor memory device 10 according to the second embodiment. FIG. 23 illustrates a portion of a cross-section of the word line WL and the memory pillar MP along the XZ plane.

The lower end portion on the end surface of the word line WL0 has, for example, a recessed shape or a rounded shape. Meanwhile, the upper end portion on the end surface of the word line WL0 has a recessed shape or a rounded shape without being deformed intentionally.

Here, as illustrated in FIG. 23, a thickness of the block insulating layer 53 facing the lower end portion on the end surface of the word line WL0 is referred to a first thickness De, and a thickness of the block insulating layer 53 facing the center portion on the end surface of the word line WL0 is referred to as a second thickness Dc. The first thickness De is different from the second thickness Dc in that the first thickness De is thicker than the second thickness Dc. The first thickness De corresponds to a distance from the lower end portion on the end surface of the word line WL0 to the charge storage layer 52, and the thickness Dc corresponds to a distance from the center portion on the end surface of the word line WL0 to the charge storage layer 52.

The structures of the word line WL0 and the memory pillar MP near the word line WL0 are described above. The same applies to the structures of the word lines WL1 and WL2 and the memory pillar MP near the word lines.

### 3.2. Method of Manufacturing Word Line and Memory Pillar

Next, a method of manufacturing the word line WL and the memory pillar MP in the semiconductor memory device 10 according to the third embodiment will be described.

In the manufacturing method according to the above-described first embodiment, the silicon oxide layer 32, the silicon oxynitride layer 60c, the silicon nitride layer 60a, and the silicon oxynitride layer 60b are stacked in order on the substrate 30. In the third embodiment, the silicon oxide layer 32, the silicon oxynitride layer 60c, and the silicon nitride layer 60a are stacked in order on the substrate 30 without forming the silicon oxynitride layer 60b. Other processes are similar to those of the manufacturing method according to the first embodiment.

### 3.3. Structures of Memory Hole Opening Region and Non-Opening Region

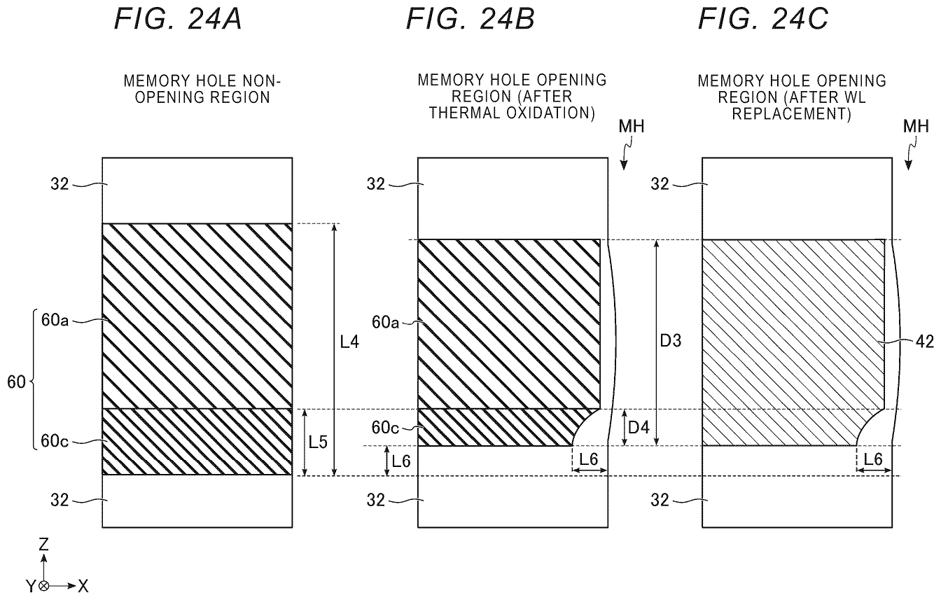

Next, structures of a memory hole opening region and a memory hole non-opening region will be compared to each other in description with reference to FIG. 24. (A) of FIG. 24 illustrates a stacked structure of the memory hole non-opening region in the semiconductor memory device 10. (B) and (C) of FIG. 24 illustrate a stacked structure of the memory hole opening region in the semiconductor memory device 10. Here, the structures corresponding to one word line WL are extracted.

In the memory hole non-opening region, oxidation is not progressed excessively and the sacrifice layer 60 is not replaced with the conductive layer 42. Therefore, in the memory hole non-opening region, almost all of the stacked sacrifice layers 60a and 60c remains. Here, as illustrated in (A) of FIG. 24, a thickness in the Z direction of the combined sacrifice layers 60a and 60c disposed in the memory hole non-opening region is referred to as L4, and a thickness in the Z direction of the sacrifice layer 60c is referred to as L5.

In the memory hole opening region, oxidation of the sacrifice layer 60c is progressed when the memory hole MH is opened and thermal oxidation is performed. Here, as illustrated in (B) of FIG. 24, an oxidation amount of the upper surface and the side surface of the sacrifice layer 60c is referred to as L6. A combined thickness of the sacrifice layers 60a and 60c after thermal oxidation is referred to as D3, and a thickness of the sacrifice layer 60c is referred to as D4.

Thereafter, the sacrifice layer 60 is replaced with the conductive layer 42. Here, a thickness of the conductive layer 42, that is, a thickness of the word line WL is the same as the combined thickness D3 of the sacrifice layers 60a and 60c.

The thickness D4 and the oxidation amount L6 are set when designing the shape of the word line WL. A combined thickness of the thickness D4 and the oxidation amount L6 is the thickness L5 of the sacrifice layer 60c in the memory hole non-opening region. In the above-described structure, the thickness D3 of the word line WL is thinner than the thickness L4 of the sacrifice layer 60 in the memory hole non-opening region.

As illustrated in FIGS. 3 and 5, the memory hole non-opening region is provided mainly in the dummy region DR, the TEG region TR, the inter-plane region PP, the edge region PR, and the contact region C4T.

### 3.4. Advantages of Third Embodiment

According to the third embodiment, as in the first embodiment, it is possible to provide a semiconductor memory device capable of improving characteristics of a memory cell and a manufacturing method thereof.

In the third embodiment, the recessed shape is formed only in the lower end portion on the end surface of the word line WL. In such a structure, it is possible to improve characteristics of the memory cell. Other advantages are similar to those of the first embodiment.

### 4. Others

The foregoing embodiments described the NAND flash memory as an example of a semiconductor memory device, but the present disclosure is not limited to the NAND flash memory. The embodiments can be applied to any of other semiconductor memories that have similar structures to the word lines and the memory cell transistors (or the memory pillars) described in the embodiments and can be applied to various semiconductor devices other than the semiconductor memories. In the flowchart described in the foregoing embodiments, the processing order can be rearranged as much as possible.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a plurality of word lines extending in a first direction and stacked in a second direction intersecting the first direction; and
a pillar penetrating the plurality of word lines in the second direction and including a first insulating layer, a second insulating layer, a third insulating layer, and a semiconductor layer extending in the second direction, wherein
a first one of the plurality of word lines, in a cross-section extended along the first and second directions, includes
an end surface with a center portion and an end portion,
the first insulating layer, the second insulating layer, the third insulating layer, and the semiconductor layer are provided in such an order from the end surface of the first word line in the first direction,
a first thickness of the first insulating layer corresponding to the end portion of the first word line and a second thickness of the first insulating layer corresponding to the center portion of the first word line are different, while the second insulating layer, the third insulating layer, and the semiconductor layer each have a sidewall linearly extending in the second direction.

2. The semiconductor memory device according to claim 1, wherein the first thickness of the first insulating layer is thicker than the second thickness of the first insulating layer.

3. The semiconductor memory device according to claim 2, wherein the first thickness corresponds to a distance from the end portion of the first word line to an interface between the second insulating layer and the first insulating layer, and the second thickness corresponds to a distance from the center portion of the first word line to the interface.

4. The semiconductor memory device according to claim 1, wherein neither the second insulating layer, nor the third insulating layer, nor the semiconductor layer protrudes toward the first word line side in the first direction.

5. The semiconductor memory device according to claim 1, wherein the end portion of the first word line has a recessed shape.

6. The semiconductor memory device according to claim 1, wherein the end portion on the end surface of the first word line is disposed at one end of the end surface in the second direction.

7. The semiconductor memory device according to claim 1, wherein the end portion on the end surface of the first word line is disposed at both ends of the end surface in the second direction.

8. The semiconductor memory device according to claim 1, wherein
the second insulating layer is provided above the first insulating layer in the first direction,
the third insulating layer is provided above the second insulating layer in the first direction, and
the semiconductor layer is provided above the third insulating layer in the first direction.

9. The semiconductor memory device according to claim 1, wherein
the first insulating layer contains silicon oxide,
the second insulating layer contains silicon nitride, and
the third insulating layer contains silicon oxide.

10. The semiconductor memory device according to claim 1, wherein
the second insulating layer includes a charge storage layer configured to store charge,
the third insulating layer includes a tunnel insulating layer, and
the semiconductor layer functions as a channel layer of a memory cell transistor.

11. The semiconductor memory device according to claim 1, further comprising:
a stacked structure including a plurality of oxide layers and a plurality of nitride layers alternately stacked in the second direction, wherein
the nitride layers each include a first nitride layer and a second nitride layer having respectively different film materials.

12. The semiconductor memory device according to claim 11, wherein the second nitride layer is more easily oxidized than the first nitride layer.

13. The semiconductor memory device according to claim 12, wherein
the first nitride layer contains silicon nitride, and
the second nitride layer contains silicon oxynitride.

14. The semiconductor memory device according to claim 1, further comprising:
a stacked structure including a plurality of oxide layers and a plurality of nitride layers alternately stacked in the second direction, and
a first memory cell array and a second memory cell array including the plurality of word lines and the pillar, and each of the first memory cell array and the second memory cell array configured to be able to independently execute a write operation and a read operation, wherein
the stacked structure is provided in at least one of a region between the first memory cell array and the second memory cell array, a peripheral region between an end portion of the substrate in which the first memory cell array is provided and the first memory cell array, a region near a contact plug connected to one word line of the plurality of word lines, and a region near a test element group (TEG).

15. The semiconductor memory device according to claim 14, wherein, in the second direction, a thickness of the first word line near the pillar is thinner than a thickness of the nitride layer of the stacked structure.

16. A method of manufacturing a semiconductor memory device, the method comprising:
forming, on a substrate, a stacked structure including a first insulating layer and a sacrifice layer stacked on top of each other in a first direction;
forming a hole in the stacked structure in the first direction;
oxidizing the sacrifice layer exposed in the hole;
forming the second insulating layer in the hole after oxidizing the sacrifice layer;
forming a nitride layer in the second insulating layer in the hole;
forming a third insulating layer in the nitride layer in the hole; and
forming a semiconductor layer in the third insulating layer in the hole.

17. The method of manufacturing a semiconductor memory device according to claim 16, wherein
the sacrifice layer includes a first sacrifice layer and a second sacrifice layer stacked in the first direction, and
the second sacrifice layer is more easily oxidized than the first sacrifice layer.

18. The method of manufacturing a semiconductor memory device according to claim 17, wherein
the first sacrifice layer contains silicon oxide,
the first sacrifice layer contains silicon nitride, and
the second sacrifice layer contains silicon oxynitride.

19. The method of manufacturing a semiconductor memory device according to claim 17, wherein the second sacrifice layer is oxidized, thereby oxidizing a portion of the second sacrifice layer exposed in the hole and forming a recessed shape in the second sacrifice layer.

20. The method of manufacturing a semiconductor memory device according to claim 16, the method further comprising:
after forming the semiconductor layer,
removing the sacrifice layer; and
forming a conductive layer in a space from which the sacrifice layer is removed.
